(19) United States
(12) Patent Application Publication
(10) Pub. No.: US 2014/0132310 A1
(43) Pub. Date: May 15, 2014

(54) DRIVING INTEGRATED CIRCUIT

(71) Applicant: NOVATEK MICROELECTRONICS CORP., Hsinchu (TW)

(72) Inventor: Li-Tang LIN, Hsinchu City (TW)

(73) Assignee: NOVATEK MICROELECTRONICS CORP., Hsinchu (TW)

(21) Appl. No.: 13/782,226

(22) Filed: Mar. 1, 2013

(30) Foreign Application Priority Data
Nov. 9, 2012 (TW) 101141757

(51) Int. Cl. H03K 19/00

(52) U.S. Cl. CPC H03K 19/0005
USPC 327/109

(57) ABSTRACT

A driving integrated circuit (IC) is disclosed. The driving IC comprises a signal processing circuit, a receiver and a terminal resistance providing circuit. The receiver is coupled to a first transmission line and a second transmission line and is output to the signal processing circuit after receiving a transmission signal through the first transmission line and the second transmission line. The terminal resistance providing circuit is coupled to the receiver.

This application claims the benefit of Taiwan application Serial No. 101141757, filed Nov. 9, 2012, the disclosure of which is incorporated by reference herein in its entirety.

### TECHNICAL FIELD

The disclosure relates in general to a driving circuit, and more particularly to a driving integrated circuit (IC).

### BACKGROUND

Flat display has now become a popular electronic product. To make the frame of the flat display looked vivid and realistic, the frame resolution and refresh rate must be increased. Therefore, the flat display with high-speed application is provided. In response to the demand for high-speed applications, the transmission line must have suitable impedance matching to resolve the difficulties in the usage frequency of the flat display caused by the reflection and decay of the transmission line.

According to the conventional application, the impedance matched terminal resistor is disposed on the printed circuit board closest to the input end of the driving IC. However, the high-speed signal entering the driving IC will inevitably pass through an impedance mismatching path, causing the high-speed signal to be distorted and lowering the highest attainable frequency of the high-speed signal.

### SUMMARY

The disclosure is directed to a driving integrated circuit (IC).

According to one embodiment, a driving integrated circuit (IC) is disclosed. The driving IC comprises a signal processing circuit, a receiver and a terminal resistance providing circuit. The receiver is coupled to a first transmission line and a second transmission line and is output to the signal processing circuit after receiving a transmission signal through the first transmission line and the second transmission line. The terminal resistance providing circuit is coupled to the receiver.

The above and other aspects of the disclosure will become better understood with regard to the following detailed description of the non-limiting embodiment (s). The following description is made with reference to the accompanying drawings.

### BRIEF DESCRIPTION OF THE DRAWINGS

FIG. 1 shows a block diagram of a driving IC with terminal resistance providing circuit;

FIG. 2 shows a schematic diagram of a driving IC according to a first embodiment;

FIG. 3 shows a schematic diagram of a driving IC according to a second embodiment;

FIG. 4 shows a schematic diagram of a driving IC according to a third embodiment;

FIG. 5 shows a schematic diagram of a driving IC according to a fourth embodiment;

FIG. 6 shows a schematic diagram of a driving IC according to a fifth embodiment;

FIG. 7 shows a schematic diagram of a driving IC according to a sixth embodiment;

FIG. 8 shows a schematic diagram of a display driving circuit according to a seventh embodiment;

FIG. 9 shows a schematic diagram of according to a display driving circuit an eighth embodiment;

FIG. 10 shows a schematic diagram of a display driving circuit according to a ninth embodiment; and

FIG. 11 shows a schematic diagram of a display according to a tenth embodiment.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

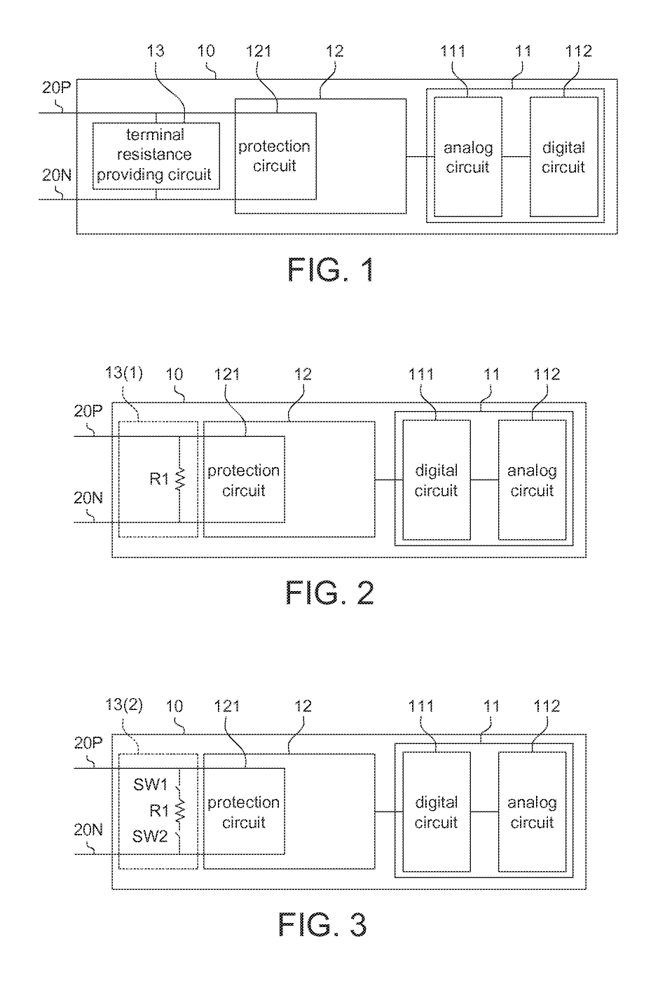

Referring to FIG. 1, a block diagram of a driving IC with terminal resistance providing circuit is shown. The driving IC 10 comprises a signal processing circuit 11, a receiver 12 and a terminal resistance providing circuit 13. The signal processing circuit 11 further comprises an analog circuit 111 and a digital circuit 112. The digital circuit 112 is coupled to the analog circuit 111, and the analog circuit 111 is coupled to the receiver 12. The receiver 12 is coupled to a transmission line 20P and a transmission line 20N, and is output to the signal processing circuit 11 after receiving the transmission signal through transmission line 20P and the transmission line 20N. For example, the driving IC 10, such as a source driving IC, receives the transmission signal generated by the timing controller. The driving IC 10 is multi-driven by a timing controller. That is, one channel of the timing controller is connected to the receiver 12 of a plurality of driving IC 10. The terminal resistance providing circuit 13 is coupled to the receiver 12. The receiver 12 further comprises a protection circuit 121 coupled to the terminal resistance providing circuit 13. The protection circuit 121 is coupled to the transmission line 20P and the transmission line 20N.

The terminal resistance providing circuit 13 is in-built in the driving IC 10, and is capable of providing a terminal resistance between the transmission line 20P and the transmission line 20N, not only shortening the impedance mismatching path and improving the quality of the transmission signal, but also increasing the highest attainable frequency of the transmission signal.

### First Embodiment

Referring to FIG. 2, a schematic diagram of a driving IC according to a first embodiment is shown. In the first embodiment, the terminal resistance providing circuit 13 is exemplified by a terminal resistance providing circuit 13(1). The terminal resistance providing circuit 13(1) comprises a terminal resistor R1. One end of the terminal resistor R1 is electrically connected to transmission line 20P, and the other end of the terminal resistor R1 is electrically connected to the transmission line 20N.

### Second Embodiment

Referring to FIG. 3, a schematic diagram of a driving IC according to a second embodiment is shown. In the second embodiment, the terminal resistance providing circuit 13 is exemplified by a terminal resistance providing circuit 13(2). The terminal resistance providing circuit 13(2) comprises a terminal resistor R1, and switches SW1 and SW2. One end of the terminal resistor R1 through is coupled to the transmission line 20P switch SW1, the terminal resistor R1 the other end of through switch SW2 is coupled to the transmission line 20N.

### Third Embodiment

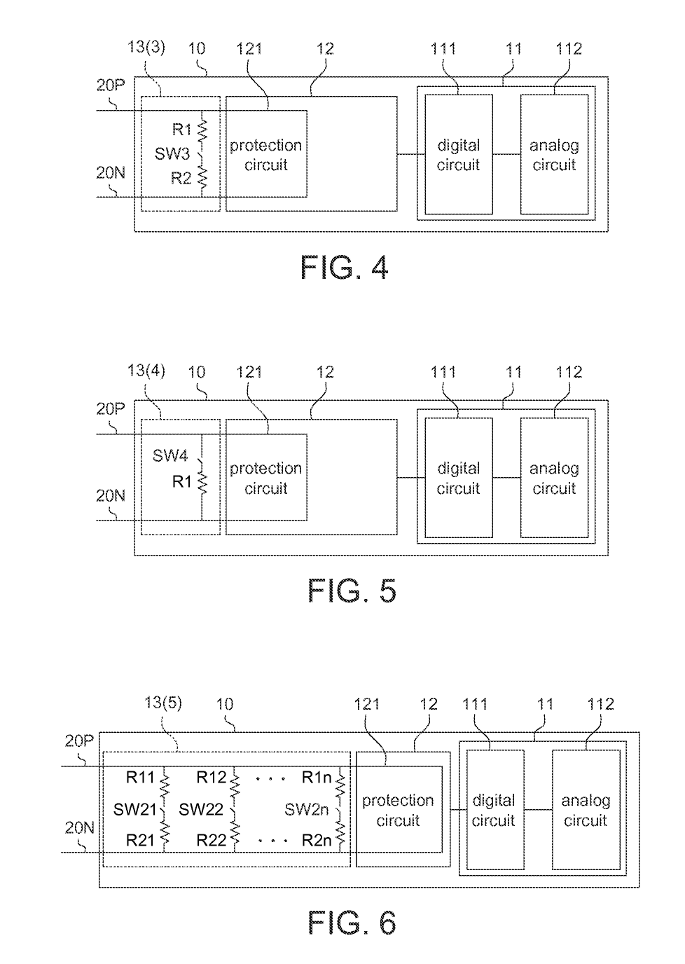

Referring to FIG. 4, a schematic diagram of a driving IC according to a third embodiment is shown. In the third embodiment, the terminal resistance providing circuit 13 is exemplified by a terminal resistance providing circuit 13(3). The terminal resistance providing circuit 13(3) comprises a switch SW3 and terminal resistors R1 and R2. One end of the switch SW3 through the terminal resistor R1 is coupled to the transmission line 20P, and the other end of the switch SW3 through terminal resistor R1 is coupled to the transmission line 20N.

### Fourth Embodiment

Referring to FIG. 5, a schematic diagram of a driving IC according to a fourth embodiment is shown. In the fourth embodiment, the terminal resistance providing circuit 13 is exemplified by a terminal resistance providing circuit 13(4). The terminal resistance providing circuit 13(4) comprises a terminal resistor R1 and a switch SW4. One end of the terminal resistor R1 through switch SW4 is coupled to the transmission line 20P, and the other end of the terminal resistor R1 is coupled to the transmission line 20N.

### Fifth Embodiment

Referring to FIG. 6, a schematic diagram of a driving IC according to a fifth embodiment is shown. In the fifth embodiment, the terminal resistance providing circuit 13 is exemplified by a terminal resistance providing circuit 13(5). The terminal resistance providing circuit 13(5) comprises switches SW21˜SW2n, terminal resistors R11˜R1n and terminal resistors R21˜R2n. One end of the terminal resistors R11˜R1n is coupled to the transmission line 20P. One end of switches SW21˜SW2n is respectively coupled to the other end of the terminal resistors R11˜R1n, the other end of switches SW21˜SW2n is respectively coupled to one end of the terminal resistors R21˜R2n, and the other end of the terminal resistors R21˜R2n is coupled to the transmission line 20N.

### Sixth Embodiment

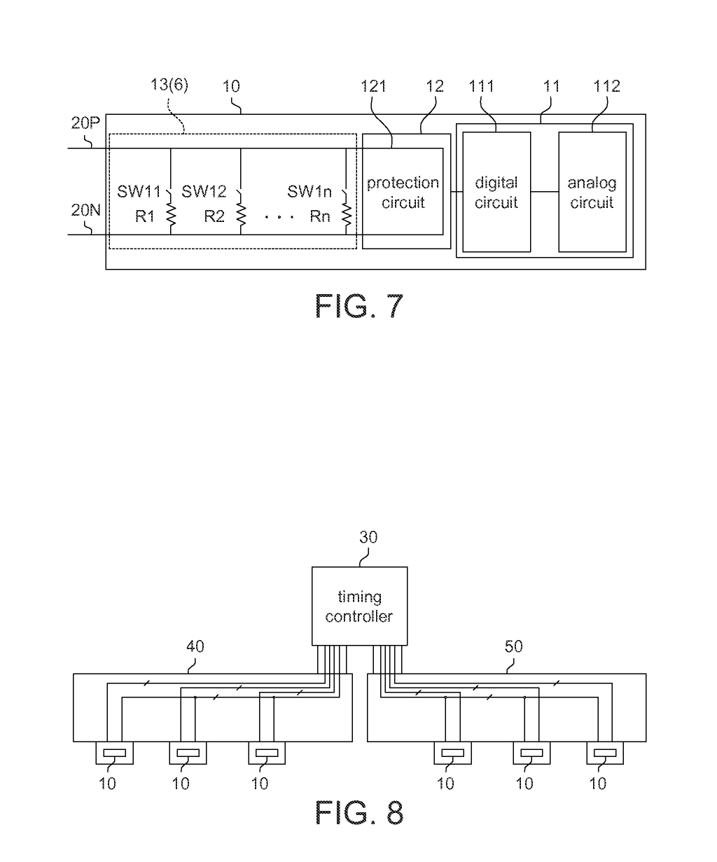

Referring to FIG. 7, a schematic diagram of a driving IC according to a sixth embodiment is shown. In the sixth embodiment, the terminal resistance providing circuit 13 is exemplified by a terminal resistance providing circuit 13(6). The terminal resistance providing circuit 13(6) comprises terminal resistors R1˜Rn and switches SW11˜SW1n. One end of the switches SW11˜SW1n is coupled to the transmission line 20P, the other end of the switches SW11˜SW1n is respectively coupled to one end of the terminal resistors R1˜Rn. The other end of the terminal resistors R1˜Rn is coupled to the transmission line 20N.

### Seventh Embodiment

Referring to FIG. 8, a schematic diagram of a display driving circuit according to a seventh embodiment is shown. It is noted that each solid line of FIG. 8 comprises a plurality of transmission lines used for transmitting the transmission signal. The timing controller 30 multi-drives a plurality of driving IC 10 through the printed circuit board 40, and multi-drives a plurality of driving IC 10 through the printed circuit board 50. The terminal resistor is in-built in the driving IC 10, not only shortening the impedance mismatching path and significantly improving the signal quality of high-speed signals, but also increasing the highest attainable frequency of high-speed signals.

### Eighth Embodiment

Referring to FIG. 9, a schematic diagram of according to a display driving circuit an eighth embodiment is shown. It is noted that each solid line of FIG. 9 comprises a plurality of transmission lines used for transmitting the transmission signal. The timing controller 30 multi-drives a plurality of driving

IC 10 through the printed circuit board 40 and the printed circuit board 50, and multi-drives a plurality of driving IC 10 through the printed circuit board 50. The terminal resistor is in-built in the driving IC 10, not only shortening the impedance mismatching path and significantly improving the signal quality of high-speed signals, but also increasing the highest attainable frequency of high-speed signals.

### Ninth Embodiment

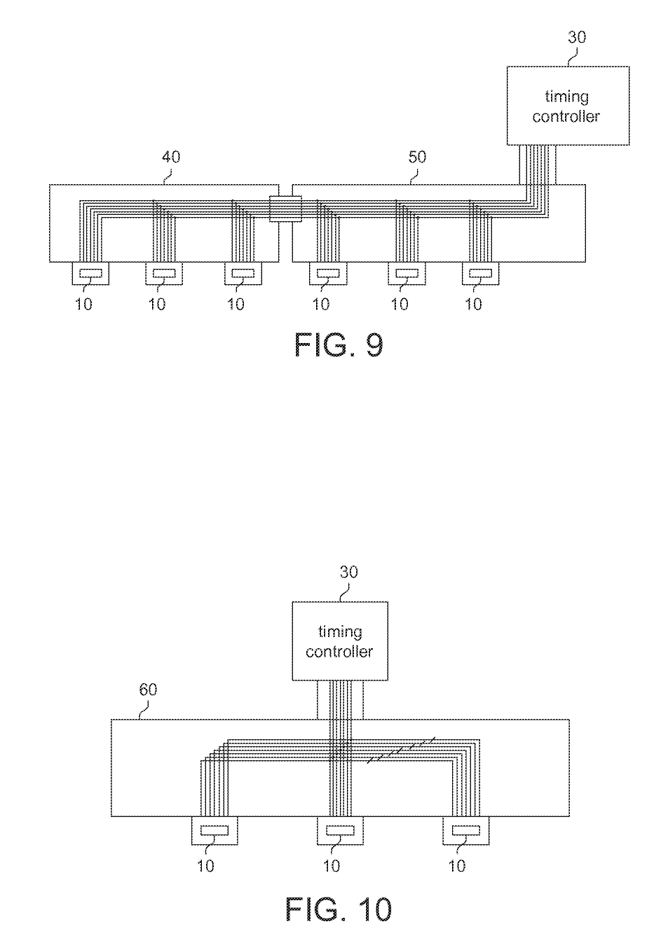

Referring to FIG. 10, a schematic diagram of a display driving circuit according to a ninth embodiment is shown. It is noted that each solid line of FIG. 10 comprises a plurality of transmission lines used for transmitting the transmission signal. The timing controller 30 multi-drives a plurality of driving

IC 10 through the printed circuit board 60. The terminal resistor is in-built in the driving IC 10, not only shortening the impedance mismatching path and significantly improving the signal quality of high-speed signals, but also increasing the highest attainable frequency of high-speed signals.

### Tenth Embodiment

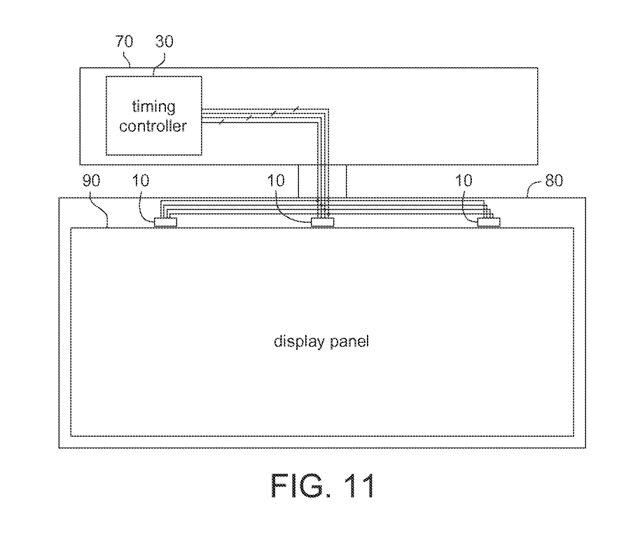

Referring to FIG. 11, a schematic diagram of a display according to a tenth embodiment. It is noted that each solid line of FIG. 11 comprises a plurality of transmission lines used for transmitting the transmission signal. The timing controller 30 is disposed on the printed circuit board 70, and the driving IC 10 and the display panel are disposed on the substrate 80 to form a chip-on-glass substrate (COG). The timing controller 30 is electrically connected to the driving IC 10 through the printed circuit board 70 and the substrate 80. The terminal resistor is in-built in the driving IC 10, not only shortening the impedance mismatching path and significantly improving the signal quality of high-speed signals, but also increasing the highest attainable frequency of high-speed signals.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A driving integrated circuit (IC), comprising:
a signal processing circuit;
a receiver coupled to a first transmission line and a second transmission line and output to the signal processing circuit after receiving a transmission signal through the first transmission line and the second transmission line; and
a terminal resistance providing circuit coupled to the receiver.

2. The driving IC according to claim 1, wherein the terminal resistance providing circuit comprises a terminal resistor whose one end is electrically connected to the first transmission line and the other end is electrically connected to the second transmission line.

3. The driving IC according to claim 2, wherein the terminal resistance providing circuit comprises a terminal resistor, a first switch and a second switch, one end of the terminal resistor is coupled to the first transmission line through the first switch, the other end of the terminal resistor is coupled to the second transmission line through the second switch.

4. The driving IC according to claim 2, wherein the terminal resistance providing circuit comprises a switch, a first terminal resistor and a second terminal resistor, one end of the switch is coupled to the first transmission line through the first terminal resistor, the other end of the switch is coupled to the second transmission line through the second terminal resistor.

5. The driving IC according to claim 2, wherein the terminal resistance providing circuit comprises a terminal resistor and a switch, one end of the terminal resistor is coupled to the first transmission line through the switch, and the other end of the terminal resistor is coupled to the second transmission line.

6. The driving IC according to claim 2, wherein the terminal resistance providing circuit comprises a plurality of switches, a plurality of first terminal resistors and a plurality of second terminal resistors, one end of the first terminal resistors is coupled to the first transmission line, one end of the switches is respectively coupled to the other end of the first terminal resistors, the other end of the switches is respectively coupled to one end of the second terminal resistors, and the other end of the second terminal resistors is coupled to the second transmission line.

7. The driving IC according to claim 2, wherein the terminal resistance providing circuit comprises a plurality of terminal resistors and a plurality of switches, one end of the switches is respectively coupled to the first transmission line, the other end of the switches is respectively coupled to one end of the terminal resistors, and the other end of the terminal resistors is coupled to the second transmission line.

8. The driving IC according to claim 1, wherein the receiver comprises a protection circuit coupled to the terminal resistance providing circuit.

9. The driving IC according to claim 1, wherein the driving IC is multi-driven by a timing controller.
